(19) United States
(12) Patent Application Publication
(10) Pub. No.: US 2024/0425357 A1
(43) Pub. Date: Dec. 26, 2024

(54) Inertial Sensor

(71) Applicant: SENSORTEK TECHNOLOGY CORP., Hsinchu County (TW)

(72) Inventors: Shih-Yuan LIU, Hsinchu County (TW); Chao-Shiun WANG, Hsinchu County (TW); Shih-Wei LEE, Hsinchu County (TW)

(21) Appl. No.: 18/242,136

(22) Filed: Sep. 5, 2023

Related U.S. Application Data
(60) Provisional application No. 63/403,442, filed on Sep. 2, 2022.

(51) Int. Cl. B81B 3/00

(52) U.S. Cl. CPC B81B 3/0062; B81B 2201/0235; B81B 2203/0154; B81B 2203/0307; B81B 2203/0323; B81B 2203/0353; B81B 2203/04; B81B 2203/056; B81B 2203/058

(57) ABSTRACT

The present application provides an inertial sensor, which comprising an anchor point, a first sensing proof mass, and a second sensing proof mass. The first sensing proof mass and the second sensing proof mass are connected with the anchor point by a corresponding flexible member. Each of the first sensing proof mass and the second sensing proof mass is provided with a groove to create mass imbalance on two sides of the flexible member for sensing accelerations in an out-of-plane direction. By mounting electrodes in a plane direction and in the grooves, in-plane accelerations orthogonal to each other are sensed.

### FIELD OF THE INVENTION

The present invention relates to an inertial sensor, especially to an inertial sensor with multi-axis sensing capability using sensing proof masses.

### BACKGROUND OF THE INVENTION

To enhance the functionality of electronic devices in the consumer electronics industry, sensors for accurate measurement of inertial motion such as inertial sensors for measurement of physical quantities including acceleration and angular velocity are mounted in electronics. Generally, acceleration in various directions and angular velocity around different axes will act on an object moved freely in a three-dimensional space. In order to detect the motion of the object precisely, acceleration along respective coordinate axes and angular velocity around the respective coordinate axes of a three-dimensional coordinate system should be measured. Thus, inertial sensors with compact size, high precision, and low production cost are required.

As mentioned above, the inertial sensors are used to measure the acceleration caused by inertial force and applied to a plurality of fields. For example, one of main driving forces for fast development of various electronic devices now is progress in human-machine interface. By intuitive operation of human bodies such as screen switch caused by flipping of an electronic device, operation interfaces are simplified and user experience is enhanced. At the same time, advanced game experience is provided by sensing human actions. Most of the electronic devices use inertial sensing devices such as velocimeters to sense the human actions. When an inertial force applied leads to deformation of mechanical structures, various sensing methods are used to calculate the acceleration or angular velocity. Now miniature inertial sensors composed of mechanical parts and circuit integrated by semiconductor technology are manufactured due to development of microelectromechanical systems (MEMS). The miniature inertial sensor has many advantages including low cost, compact volume, etc.

The miniature inertial sensors are divided into several types according to different sensing methods. A basic type among the inertial sensors currently available comprises a sensing proof mass. When the sensing proof mass is accelerated and undergoes displacement, a distance between the proof mass and a sensing electrode is changed. The changes have been read by operation circuit of the device (sensor) and converted into signals representing acceleration. Thereby the inertial sensor currently available can calculate accelerations in multiple axes by using one sensing proof mass, as the inertial sensor provided in Taiwanese Pat. Pub. No. 202240170 applied by the same applicant of the present invention.

An inertial sensor with fully differential design is provided to eliminate multi-axis interference. Two sets of independent components are used to detect and each set of the component comprises an anchor point, a frame, a sensing proof mass, and flexible members. That means the device is formed by two sets of inertial sensors without interference with each other. It is learned that development of the fully differential inertial sensor needs a lot of area for two sets of inertial sensors completely the same with each other but the two inertial sensor can't share the respective components. Thereby such design has no advantages in area and cost and thus its market acceptance is still unable to be improved significantly.

Thus there is room for improvement and there is a need to provide a novel inertial sensor which solves the problem of multi-axis interference of the existing inertial sensor.

### SUMMARY

Therefore, it is a primary of the present invention to provide an inertial sensor which solves the problems of area and cost mentioned above.

In order to achieve the above object, an inertial sensor according to the present invention comprises an anchor point, a first sensing proof mass, and a second sensing proof mass. The first sensing proof mass is connected with the anchor point by a flexible member while the second sensing proof mass is connected with the anchor point by another flexible member. The first sensing proof mass is provided with a first groove to create mass imbalance on two sides of the flexible member while the second sensing proof mass is provided with a second groove to cause mass imbalance on two sides of the other flexible member. The first sensing proof mass and the second sensing proof mass are disposed on two sides of the anchor point in the first axial direction. A second axial direction is perpendicular to the firs axial direction. In the second axial direction, the anchor point is located at a middle part of the first sensing proof mass or the second sensing proof mass.

The two symmetrically arranged sensing proof masses are fixed by only single anchor point and mass imbalance is created by forming grooves in the sensing proof masses for sensing accelerations in an out-of-plane direction. By mounting electrodes in a plane direction in the grooves, in-plane accelerations orthogonal to each other are sensed. The above structure of the present invention provides higher structural consistency and isotropy. Therefore, overall performance of the inertial sensor is improved, complexity of operation circuit is simplified, and the inertial sensor has good sensitivity to displacement in the respective axial directions.

### BRIEF DESCRIPTION OF THE DRAWINGS

FIG. 1A is a schematic drawing showing structure of an embodiment of an inertial sensor according to the present invention;

FIG. 1B is a schematic drawing showing arrangement of sensing electrodes of an embodiment of an inertial sensor according to the present invention;

FIG. 2A is a schematic drawing showing an inertial force in a first axial direction acted on an embodiment according to the present invention;

FIG. 2B is a schematic drawing showing an inertial force in a second axial direction applied to an embodiment according to the present) invention;

FIG. 3 is a schematic drawing showing an embodiment which comprises sensing proof masses of different sizes according to the present invention;

FIG. 4A is a schematic drawing showing structure of an embodiment in which main components are disposed in a non-totally symmetric manner according to the present invention;

FIG. 4B is a schematic drawing showing structure of an embodiment which is provided with only a single set of inertial sensing units according to the present invention;

FIG. 4C is a schematic drawing showing structure of an embodiment in which a position of an anchor point is adjusted according to the present invention;

FIG. 5A is a schematic drawing showing strain of an embodiment of an inertial sensor in which an anchor point is arranged at a center of the structure according to the present invention;

FIG. 5B is a schematic drawing showing asymmetric strain caused during packaging process according to the present invention.

### DETAILED DESCRIPTION

In order to understand features and functions of the present invention more clearly, please refer to the following embodiments, related figures and descriptions.

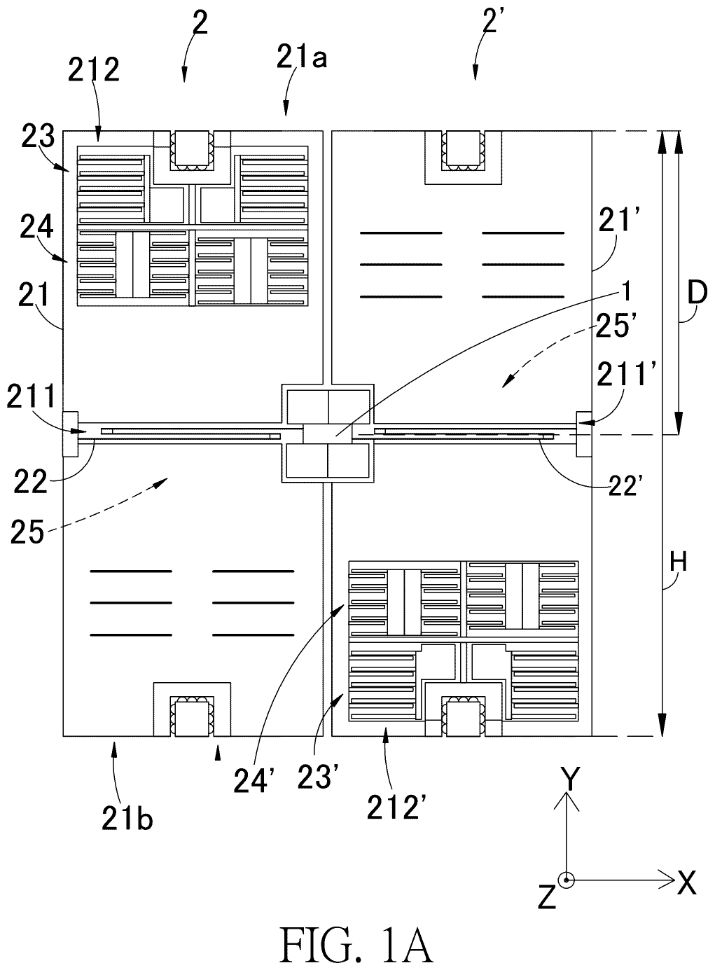

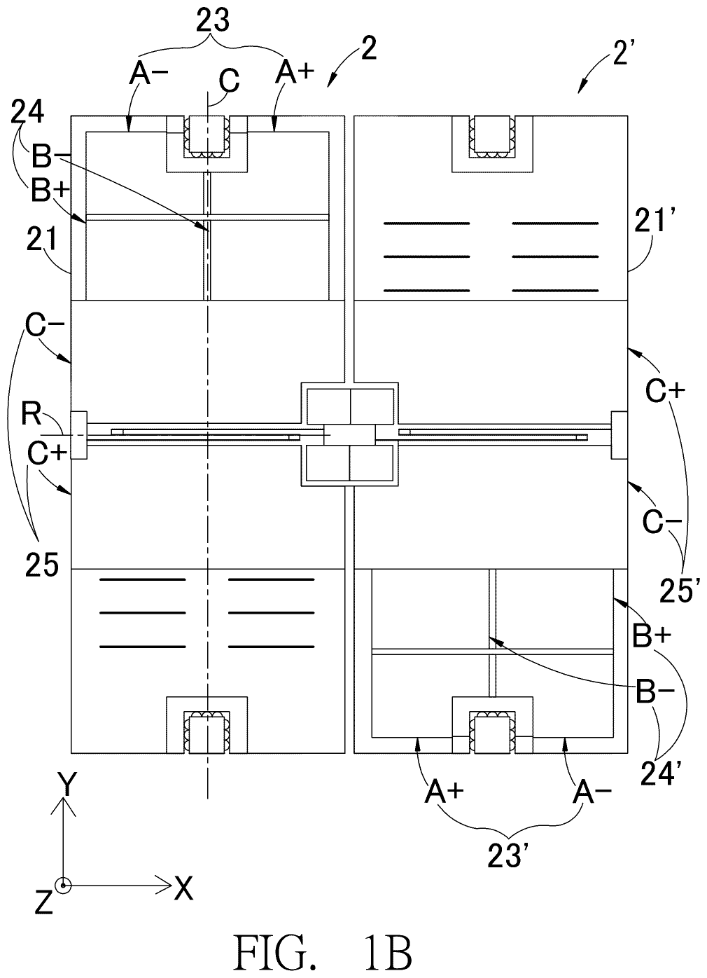

Referring to FIG. 1A, which provides a schematic drawing showing structure of a first embodiment of an inertial sensor according to the present invention is provided. The inertial sensor comprises an anchor point 1 and two sets of inertial sensing units 2, 2′. For ease of explanation, a three-axis coordinate is used to describe the first embodiment of the inertial sensor, where a first axial direction X, a second axial direction Y, and a third axial direction Z are perpendicular to one another. The anchor point 1 is a fixed point of a system architecture, usually fixed on a substrate and the two sets of inertial sensing units 2, 2′ are disposed on two sides of the anchor point 1 in the first axial direction X and basically have the same structure. Thus only the inertial sensing unit 2 on the left side of the figure is described in the following for explanation. The inertial sensing unit 2 comprises a sensing proof mass 21, a flexible member 22, and a plurality sets of sensing electrodes 23, 24, 25.

On an X-Y plane formed by the first axial direction X and the second axial direction Y, the sensing proof mass 21 is designed to be a square or a rectangle having a short side in parallel to the first axial direction X in order to facilitate manufacturing. The anchor point 1 is located on one side of the sensing proof mass 21 in the first axial direction X. As shown in the figure, the anchor point 1 is on the right side of the sensing proof mass 21 in the first axial direction X. Similarly, for a sensing proof mass 21′ of the other inertial sensing unit 2′, the anchor point 1 is located at its left side. The flexible member 22 is connected with the anchor point 1 and extends toward the sensing proof mass 21 in the first axial direction X to be connected with the sensing proof mass 21. The sensing proof mass 21 is provided with a long hole 211 for mounting the flexible member 22. The longer the flexible member 22, the more easily the flexible member 22 deforms. Thereby, the sensing proof mass 21 has larger displacement while being affected by an inertial force and this provides multiple advantages. The related principle of such design has been disclosed in the patent mentioned above.

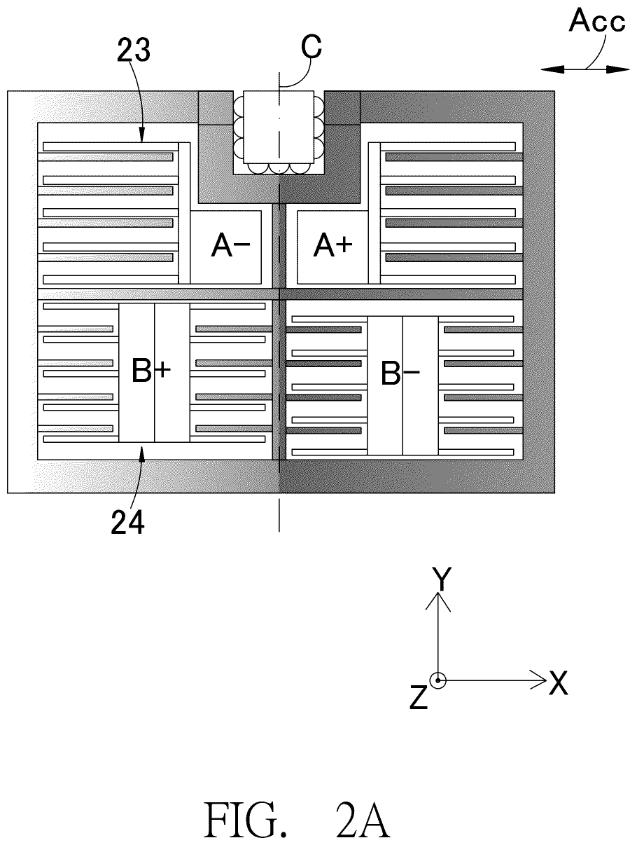

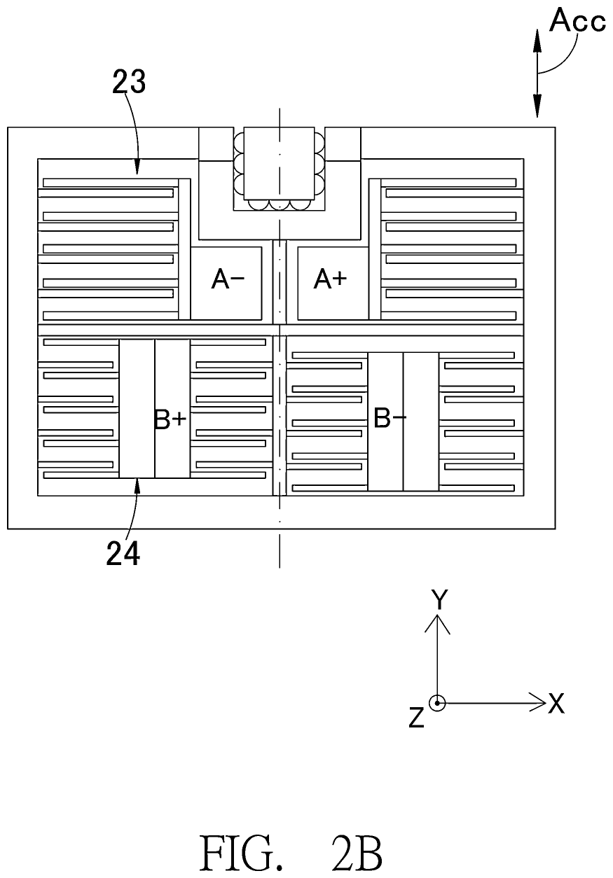

It should be noted that the sensing proof mass in an existing inertial sensor with out-of-plane sensing capabilities currently available is tilting due to mass imbalance. In such a design, the most common structure to cause the mass imbalance is by swing of flexible members (such as in the patent mentioned above, a first gap G1 is larger than a second gap G2 in an embodiment shown in FIG. 2). In order to design a fully differential system, the two sets of independent parts are unable to use the same anchor point because flexible members are not located at the center of the system. The increased number of anchor points not only leads to low area efficiency but also makes multi-input of external stress easier and thus forming more static offset. In the following embodiment, how the present inertial sensor overcomes these problems and achieves a fully differential design is described in detail.

In this embodiment, the flexible member 22 is arranged at the middle part of the device. This means the position of the anchor point 1 is preferably at the middle part of the sensing proof mass 21 in the second axial direction Y. For the sensing proof mass 21′ of the other inertial sensing unit 2′, the anchor point 1 is also located at the middle part of the sensing proof mass 21′in the second axial direction Y. Thereby, the two sets of inertial sensing units 2, 2′ can share the same anchor point 1. In order to make the sensing proof mass 21 tilt, a groove 212 is mounted on the sensing proof mass 21 so that masses of the sensing proof mass 21 on two sides of the flexible member 22 are imbalanced. Consequently, weights of the sensing proof mass 21 distributed on two sides of the anchor point 1 in the second axial direction Y are not equal. While receiving an inertial force in specific direction (such as the third axial direction Z), the sensing proof mass 21 is tilting and its operation is described in the following.

In consideration of manufacturing accuracy, structural strength, assembly difficulty etc., the anchor point 1 has a certain volume during manufacturing. The anchor point 1 described is located at the middle of the sensing proof mass 21. This is defined by a distance D between one side edge 21a of the sensing proof mass 21 and the anchor point 1 in the second axial direction Y. A length H is formed between two side edges 21a, 21b of the sensing proof mass 21 in the second axial direction Y and the distance D is equal to 40%˜60% of the length H, with 45%˜55% being preferred.

Moreover, the groove 212 is for mounting the aforementioned sensing electrodes 23, 24. A set of first sensing electrodes 23 is disposed in the groove 212 for sensing movement of the sensing proof mass 21 driven by inertial force in the first axial direction X. Similarly, a set of second sensing electrodes 24 is mounted in the groove 212 for sensing movement of the sensing proof mass 21 driven by inertial force in the second axial direction Y. A set of third sensing electrodes 25 is arranged on a bottom surface of the sensing proof mass 21 in the third axial direction Z for sensing movement of the sensing proof mass 21 driven by inertial force in the third axial direction Z.

As shown in FIG. 1B, in this embodiment, each set of the sensing electrodes 23, 24, 25 preferably comprises two electrodes with opposite polarities. A positive electrode A+ and a negative electrode A− of the first sensing electrodes 23 are preferably arranged in the groove 212 symmetrically with respect to a central line C of the sensing proof mass 21 where the central line C is perpendicular to the first axial direction X. A positive electrode B+ and a negative electrode B− of the second sensing electrodes 24 are preferably disposed in the groove 212 symmetrically with respect to the central line C of the sensing proof mass 21. A positive electrode C+ and a negative electrode C− of the third sensing electrodes 25 are preferably mounted symmetrically with respect to an axial line R that runs across the anchor point 1 and is parallel to the first axial direction X.

In the following embodiments, how the respective sets of the sensing electrodes 23, 24, 25 detect movement of the sensing proof masses is described. As shown in FIG. 2A, when the inertial force in the first axial direction X acts on the sensing proof mass 21, the sensing proof mass 21 rotates and the flexible member 22 further undergoes deformation similar to deflection with respect to the anchor point 1. The first sensing electrodes 23 then detect movement of the sensing proof mass 21 on which the inertial force in the first axial direction acts. More specifically, the sensing proof mass 21 experiences an acceleration Acc in the first axial direction X with the central line C as a baseline because the positive electrode A+ and the negative electrode A− of the first sensing electrodes 23 are arranged symmetrically with respect to the central line. When the positive electrode A+ senses a displacement in the first axial direction X and outputs a positive variable +Δ, the negative electrode A− outputs a negative variable −Δ while sensing the same displacement. Thus, the first sensing electrodes 23 produce a differential output which is equal to a total variable of -(+Δ)-(−Δ)=2Δ. At the same time, the positive electrode B+ and the negative electrode B− of the second sensing electrodes 24 are also arranged symmetrically with respect to the central line C. When the positive electrode B+ senses the displacement in the first axial direction X and outputs a negative variable −Δ, the negative electrode B− also outputs a negative variable −Δ while sensing the same displacement. Thus, signal cancellation occurs in the second sensing electrodes 24.

Referring to FIG. 2B, while being acted by the inertial force in the second axial direction Y, the sensing proof mass 21 undergoes translational motion. One side of the flexible member 22 is connected with the anchor point 1 (unable to translate) while the other side of the flexible member 22 is connected with the sensing proof mass 21 (able to translate), causing the flexible member 22 to deform in a manner similar to bending. The second sensing electrodes 24 are used to sense movement of the sensing proof mass 21 under influence of the inertial force in the second axial direction Y. More specifically, the sensing proof mass 21 is accelerated in the second axial direction Y with the central line C as a baseline. The positive electrode A+ and the negative electrode A− of the first sensing electrodes 23 are arranged symmetrically with respect to the central line C. When the positive electrode A+ of the first sensing electrodes 23 detects a displacement in the second axial direction Y and outputs a negative variable −Δ, the negative electrode A− also outputs a negative variable −Δ while detecting the same displacement. Thus signal cancellation occurs in the first sensing electrodes 23. At the same time, in the second sensing electrodes 24, the positive electrode B+ and the negative electrode B− of the second sensing electrodes 24 are also arranged symmetrically with respect to the central line C. When the positive electrode B+ detects the displacement in the second axial direction Y and outputs a positive variable +Δ, the negative electrode B− outputs a negative variable −Δ while detecting the same displacement. Consequently, the second sensing electrodes 24 produce a differential output which is equal to a total variable of (+Δ)-(−Δ)=2Δ.

It should be noted that there is no description related to the third sensing electrodes 25 in FIG. 2A and FIG. 2B. This is because regardless of whether the sensing proof mass 21 is accelerated in the first axial direction X or the second axial direction Y, both result in in-plane displacement on the X-Y plane. Thus differential cancellation occurs while sensing the in-plane displacement through the positive electrode C+ and the negative electrode C− of the third sensing electrodes 25.

Referring to FIG. 1B, when an inertial force is applied in the third axial direction Z, weights of the sensing proof mass 21 distributed on two sides of the anchor point 1 in the second axial direction Y are not equal, causing the sensing proof mass 21 to tilt, lifting off the X-Y plane and causing the flexible member 22 to undergo torsion-like deformation. The third sensing electrodes 25 are used to detect movement of the sensing proof mass 21 when the inertial force is applied in the third axial direction Z. In detail, the out-of-plane movement of the sensing proof mass 21 can be considered as pivoting rotation around the flexible member 22. The positive electrode C+ and the negative electrode C− of the third sensing electrodes 25 are arranged symmetrically with respect to the axial line R while the flexible member 22 is nearly overlapped with the axial line R, allowing the third sensing electrodes 25 to produce a differential output. It also should be noted that when the sensing proof mass 21 is tilting, both the first sensing electrodes 23 and the second sensing electrodes 24 are moved upward or downward synchronously in the third axial direction Z. Thus differential cancellation occurs on the two sets of the positive and negative electrodes A+, A−, B+, and B− thereof.

In addition to being disposed on the two sides of the anchor point 1 in the first axial direction X, the two sets of inertial sensing units 2, 2′ with vertical symmetry are also arranged symmetrically with respect to the anchor point 1 in the second axial direction Y in order to form a fully differential system. In short, take the embodiment in FIG. 1A and FIG. 1B as an example, the first sensing electrodes 23 and the second sensing electrodes 24 of the inertial sensing unit 2 are mounted in the grooves 212 of the sensing proof mass 21 located above the anchor point 1 while the first sensing electrodes 23′ and the second sensing electrodes 24′ of the other inertial sensing unit 2′ are mounted in the grooves 212′ of the sensing proof mass 21′ located below the anchor point 1. If the positive electrode C+ and the negative electrode C− of the third sensing electrodes 25 of the inertial sensing unit 2 are respectively arranged below and above the anchor point 1, the positive electrode C+ and the negative electrode C− of the third sensing electrodes 25′ of the other inertial sensing unit 2′ are respectively disposed above and under the anchor point 1.

The advantages of the first embodiment in which the two sets of inertial sensing units 2, 2′ share the same anchor point 1 are described as follows.

In the first embodiment, a single anchor point is disposed on a substrate for fixing two sensing proof masses arranged symmetrically to each other in an inertial sensor. The anchor point is connected with each of the sensing proof masses by a flexible member. Mass imbalance is created by forming grooves in the sensing proof masses for sensing acceleration in an out-of-plane direction. By mounting electrodes in a plane direction, in-plane accelerations orthogonal to each other are sensed. According to the above design, the flexible members for connecting the sensing proof masses are designed to be located at a middle part of the whole structure so that the two sensing proof masses are connected only by the single anchor point at the middle part. Consequently, deformation caused by external stress is only transferred to the respective sensing proof masses through the single anchor point at the center. Compared with prior techniques using system with multiple anchors and swing of flexible members, the first embodiment has higher structural consistency and isotropy.

Moreover, by utilizing a fully differential circuit composed of completely symmetrical components, not only can deformation generated due to external stress (from sources such as temperature, pressure, etc.) be eliminated effectively and static offset reduced, but the noise is also reduced and signal-to-noise ratio is increased. Consequently, the overall performance of the inertial sensor is significantly improved.

It should also be noted that the two sensing proof masses are two independent components, without being coupled by any other structure. At the same time, the respective sets of the sensing electrodes on each of the sensing proof masses are provided with two electrodes having opposite polarities and arranged at the aforementioned positions to perform calculations such as differential output and differential cancelation and avoid multi-axis interference. There is no need to divide the electrode with the same polarity into multiple parts arranged at different positions and perform different processing on signals of different electrodes along with different acceleration going to be sensed. Compared with prior techniques, complexity of operation circuit can be simplified significantly.

On the other hand, the slots mounted on the respective sensing proof masses in the embodiment not only create mass imbalance but also allow two sets of sensing electrodes for sensing in-plane movement to mount therein. There is no need to enlarge the sensing proof masses or dispose frame systems for improving area efficiency. The sensing proof mass provides sufficient area in the second axial direction Y for arrangement of electrodes which sense out-of-plane movement. People having ordinary skill in the art can understand that the out-of-plane movement of the sensing proof mass could possibly be the minimum displacement in the three axial directions. By the design of saving length in the second axial direction Y, space for arrangement of out-of-plane sensing electrodes and design flexibility can be maximized. Therefore, the inertial sensor has good sensitivity to displacement in the respective axial directions.

The following are other embodiments of the present invention.

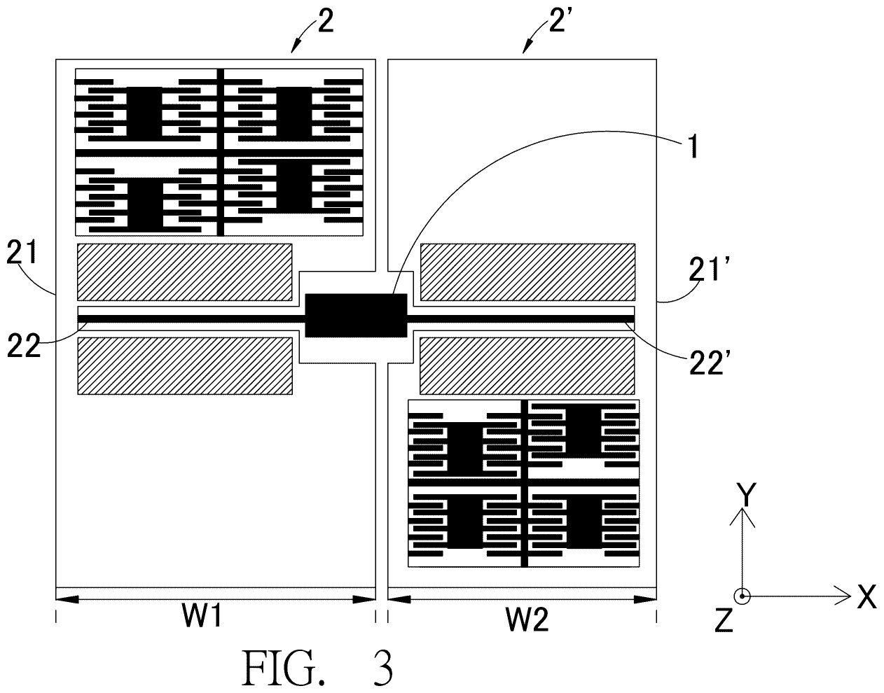

Referring to FIG. 3, the two sets of inertial sensing units 2, 2′ in the above embodiment essentially have the same structure. Designers can also make some modification according to their needs. For example, when there is a limited space or under special application condition, the two sets of inertial sensing units 2, 2′ are designed to have different structures such as the sensing proof masses 21, 21′ with different sizes. More specifically, a width W1 of the sensing proof mass 21 of the inertial sensing unit 2 in the first axial direction X is larger than a width W2 of the sensing proof mass 21′ of the other inertial sensing unit 2′ in the first axial direction X while the anchor point 1 is still located at a middle part of the respective sensing proof masses 21, 21′ in the second axial direction Y and the sensing proof masses 21, 21′ still share the same anchor point 1. The flexible members 22, 22′ for connecting the sensing proof masses 21 21′ with the anchor point 1 also differ in size. However, the embodiment in FIG. 3 can still be considered as an inertial sensor quite close to the fully differential system through subsequent weighted operation.

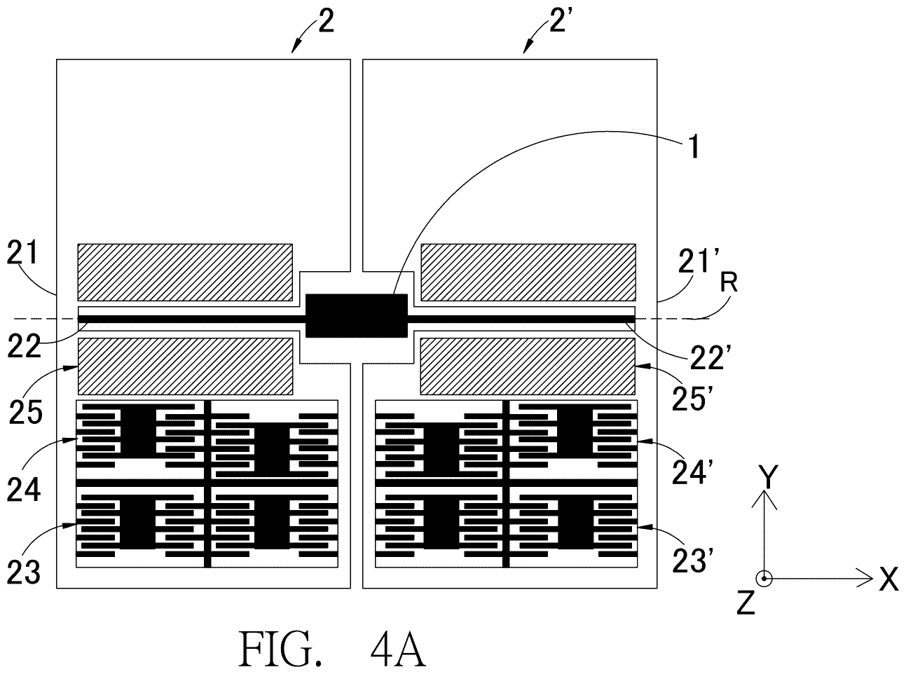

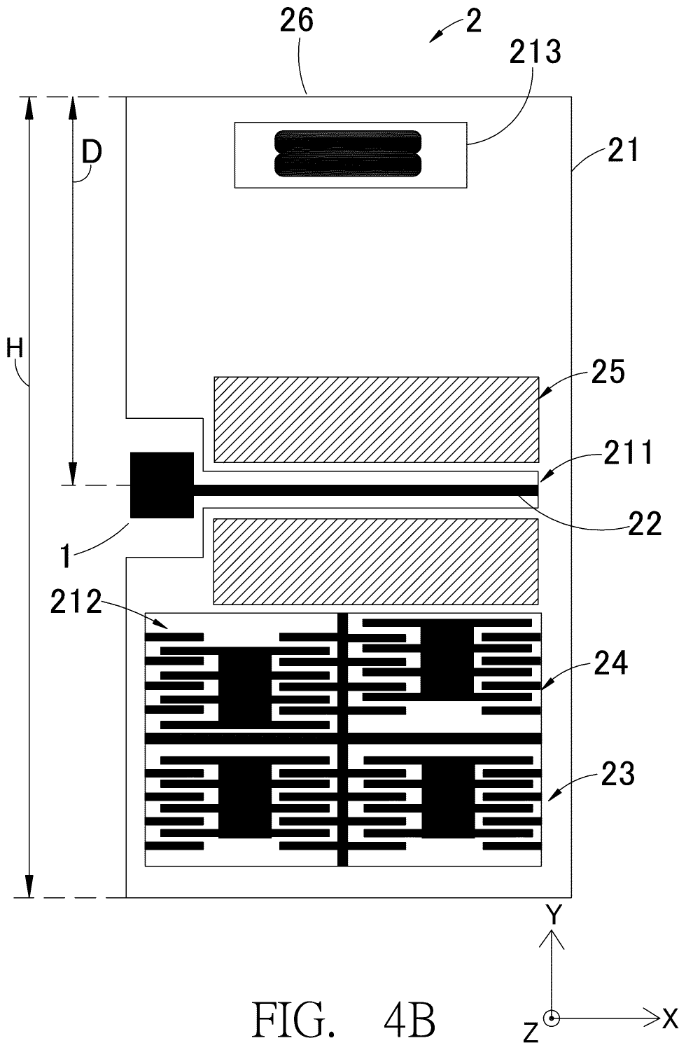

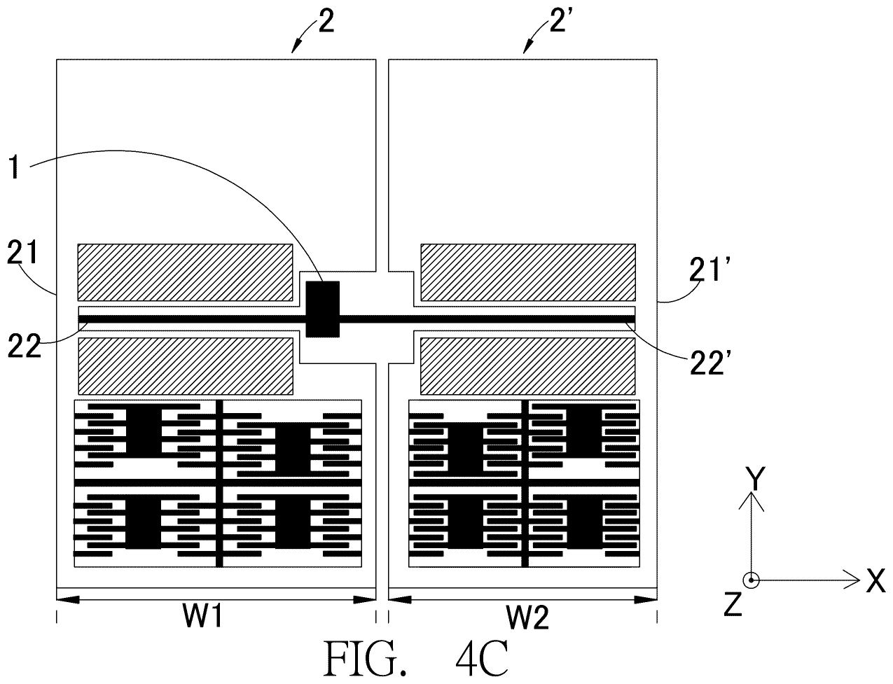

However, the present invention is not limited to the inertial sensor of the fully differential system. As shown in FIG. 4A, the two sets of inertial sensing units 2, 2′ are disposed on two sides of the anchor point 1 in the first axial direction X to form a vertical line symmetry. If designers determine that effects of external stress on the inertial sensor in the second axial direction Y can be neglected, the two sets of inertial sensing units 2, 2′ can be arranged at the same side of the anchor point 1 in the second axial direction Y. That means the two sets of inertial sensing units 2, 2′ are in a reflection symmetry (mirror symmetry) with respect to the anchor point 1 with a line of symmetry perpendicular to the first axial direction X. This embodiment is still a breakthrough inertial sensor and the design only slightly affects some of the advantages of the above embodiment such as improved overall performance of the inertial sensor by the fully differential system.

Referring to FIG. 4B, which illustrates a further embodiment comprising only a single set of sensing unit 2 is provided. Mass imbalance is created and placement of planar sensing electrodes 23, 24 is achieved by formation of the groove 212 in the sensing proof mass 21. By arrangement of the electrodes 23, 24 in parallel, the length in the second axial direction Y is left to planar electrodes 25 as much as possible. Under such condition, the anchor point 1 can be disposed on a middle part. Consequently, the structure has higher symmetry and consistency when deformation under external stress is transferred to the sensing proof mass 21 and static offset caused by external conditions is further reduced. According to users' needs, the embodiment can even be provided with a slotted hole 213 at other positions of the sensing proof mass 21 for mounting other components (such as a stopping member 26). In other words, the embodiment still has a certain market value even its not a is a fully differential or partial differential inertial sensor compared with other existing inertial sensors which create mass imbalance by swing of flexible members.

Referring to FIG. 4C, this is a combination of the above two embodiments. It should be noted that removed parts of the two sensing proof masses 21, 21′ are both on a lower part of the figure and the two sensing proof masses 21, 21′ have different sizes. These factors lead to the center of gravity of the overall inertial sensor being more on the upper left side in the figure. Under such condition, the position of the anchor point 1 can be adjusted and moved to the upper left side in the figure to maintain consistency of the whole structure in order to make stress propagation more uniform.

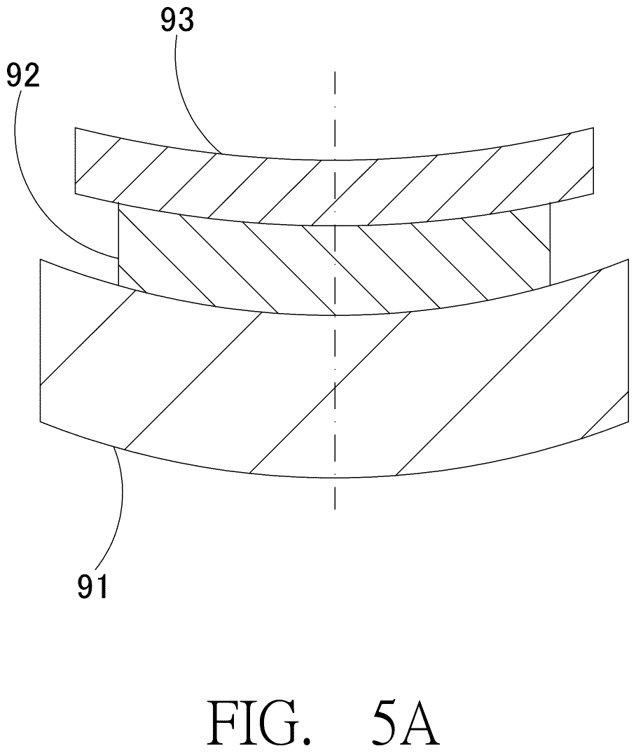

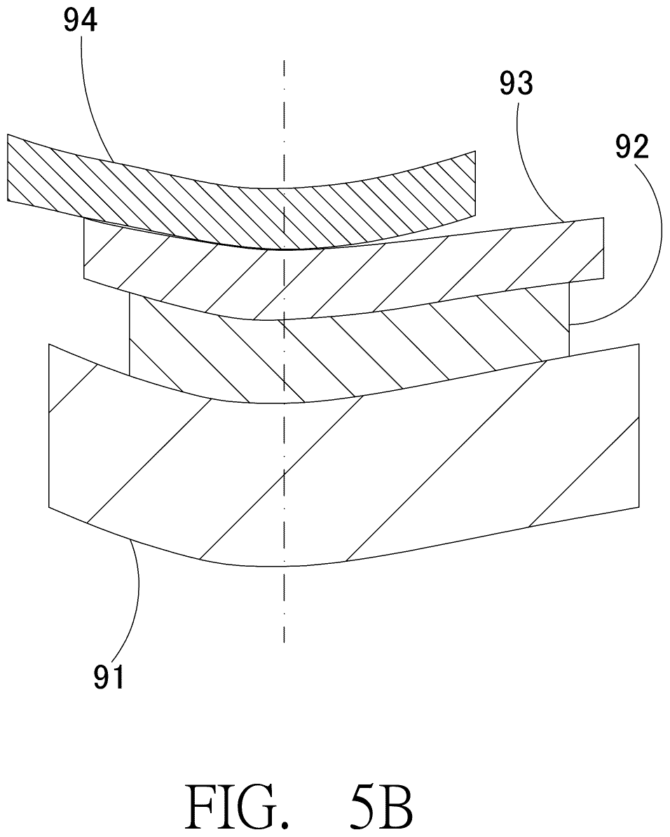

Generally, a MEMS sensor comprises three layers formed by a substrate layer 91, a device layer 92, and a cap layer 93. As shown in FIG. 5A, the sensor experiences strain when subjected to external stress, and such strain causes the sensor to receive unexpected output signals. It is supposed that the strain caused by the stress is with a certain symmetry. When the symmetry is applied to electrodes, the unexpected output signals can cancel each other out. One of the effective way for improvement of symmetry of the strain is the same as mentioned above: the anchor point (a structure connected with the substrate layer 91 or the cap layer 93) is placed at a central area to improve the symmetry of the strain the sensor received.

In real-world situation, designers must consider multiple factors when implementing the present invention. The strain may be not central symmetric due to various factors such as features and performance of the sensor after component packaging. Take an embodiment in FIG. 5B as an example. Respective layers of an application specific integrated circuit (ASIC) 94 are not stacked and packaged with their centers aligned and this may cause the strain is not central symmetric. In this case, positions of the anchor point and the sensing proof masses of the sensor should be adjusted, bot limited to a central area of the sensor itself in order to maintain symmetry of the strain.

Therefore, the present invention is novel, non-obvious, and useful meeting major requirements for patentability.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. An inertial sensor comprising:
an anchor point;
a first sensing proof mass connected with the anchor point by a first flexible member and provided with at least one first groove for creating mass imbalance of the first sensing proof mass on two sides of the first flexible member; and
a second sensing proof mass connected with the anchor point by a second flexible member and provided with at least one second groove for creating mass imbalance of the second sensing proof mass on two sides of the second flexible member;
wherein the first sensing proof mass and the second sensing proof mass are arranged at two sides of the anchor point in a first axial direction; a second axial direction is perpendicular to the first axial direction; the anchor is located at a middle part of the first sensing proof mass or the second sensing proof mass in the second axial direction.

2. The inertial sensor as claimed in claim 1, wherein a distance is formed between an upper side edge of the first sensing proof mass and the anchor point in the second axial direction; the first sensing proof mass has a length in the second axial direction; the distance is equal to 40%˜60% of the length.

3. The inertial sensor as claimed in claim 2, wherein the distance is equal to 45%˜55% of the length.

4. The inertial sensor as claimed in claim 1, wherein the first sensing proof mass is provided with a first long hole; the first flexible member is extending from the anchor point toward the first sensing proof mass in the first long hole in the first axial direction for connection with the first sensing proof mass; wherein the second sensing proof mass is provided with a second long hole; the second flexible member is extending from the anchor point toward the second sensing proof mass in the second long hole in the first axial direction for connection with the second sensing proof mass.

5. The inertial sensor as claimed in claim 1, wherein the first groove is used for mounting a plurality sets of sensing electrodes and the second groove is used for mounting a plurality sets of sensing electrodes.

6. The inertial sensor as claimed in claim 5, wherein a set of first sensing electrodes is mounted in the first groove for sensing acceleration of the first sensing proof mass in the first axial direction; a set of second sensing electrodes is mounted in the first groove for sensing acceleration of the first sensing proof mass in the second axial direction.

7. The inertial sensor as claimed in claim 5, wherein a set of third sensing electrodes is arranged on a surface of the first sensing proof mass in the third axial direction for sensing acceleration of the first sensing proof mass in the third axial direction.

8. The inertial sensor as claimed in claim 6, wherein the first sensing electrodes comprise a positive electrode and a negative electrode which are arranged in the first groove symmetrically with respect to a central line of the first sensing proof mass; the central line is perpendicular to the first axial direction; the second sensing electrodes comprise a positive electrode and a negative electrode which are mounted in the first groove symmetrically with respect to the central line.

9. The inertial sensor as claimed in claim 7, wherein the third sensing electrodes comprise a positive electrode and a negative electrode which are arranged symmetrically with respect to an axial line; the axial line runs across the anchor point and in parallel to the first axial direction.

10. The inertial sensor as claimed in claim 5, wherein the first groove and the second groove are located on two side of an axial line which runs across the anchor point and parallel to the first axial direction correspondingly.

11. The inertial sensor as claimed in claim 5, wherein the first groove and the second groove are located at the same side of an axial line which runs across the anchor point and parallel to the first axial direction.

12. The inertial sensor as claimed in claim 7, wherein another set of third sensing electrodes is disposed on a surface of the second sensing proof mass in the third axial direction for sensing acceleration of the second sensing proof mass in the third axial direction.

13. The inertial sensor as claimed in claim 1, wherein a width of the first sensing proof mass in the first axial direction is equal to a width of the second sensing proof mass in the first axial direction.

14. The inertial sensor as claimed in claim 1, wherein a width of the first sensing proof mass in the first axial direction is larger than a width of the second sensing proof mass in the first axial direction.
